(19) United States
(12) Patent Application Publication
(10) Pub. No.: US 2007/0242719 A1
(43) Pub. Date: Oct. 18, 2007

(54) Optical manipulator illuminated by patterned organic microcavity lasers

(75) Inventors: John P. Spoonhower, Webster, NY (US); David L. Patton, Webster, NY (US); Keith B. Kahen, Rochester, NY (US)

Correspondence Address: Pamela R. Crocker, Patent Legal Staff;Eastman Kodak Company, 343 State Street, Rochester, NY, 14650-2201, US

(73) Assignee: Eastman Kodak Company

(21) Appl. No.: 11/403,047

(22) Filed: Apr. 12, 2006

(51) Int. Cl. H01S 5/00

(52) U.S. Cl. 372/50.124

(57) ABSTRACT

The present disclosure relates to an optical device and technique for manipulating microscopic objects. The device includes a support to locate microscopic objects. A laser array assembly that includes a plurality of organic laser devices generates an image onto the support via an objective lens. A control device controls the plurality of the organic laser devices to vary the image on the support and manipulate the microscopic objects disposed on the support.

### FIELD OF THE INVENTION

The present invention relates to organic lasers, and more specifically to a organic microcavity laser for manipulating microscopic objects.

### BACKGROUND OF THE INVENTION

Optical tweezers use light to manipulate microscopic objects as small as a single atom. The radiation pressure from a focused laser beam is able to trap and move small particles. In the biological area, these methods and instruments are used to apply forces in the pN-range and to measure displacements in the nanometer range of objects ranging in size from 10 nm to over 100 mm. In the most basic form a laser beam is focused by a high-quality microscope object to a spot on the specimen plan. The spot creates an “optical trap” which is able to hold a small particle at its center.

The prior art as shown in FIG. 1 illustrates an optoelectronic tweezers (OET) device 10 used to manipulate biological cells and micrometer-scale particles 15. The cells or particles 15 which are to be manipulated are contained in a liquid (not shown) sandwiched between an upper transparent, conductive ITO-coated glass 20 and a lower photoconductive support structure 25 sitting on a glass substrate 27. The photoconductive support structure 25 consists of several featureless layers of ITO-coated glass 30, an n⁺ hydrogenated amorphous silicon (a-Si:H) layer 32, an undoped a-Si:H layer 34, and a silver nitride layer 36. These two surfaces are biased with 10Vₚₚ AC signal created by an AC signal generator 38.

A digital micro mirror display (DMD) 40 is illuminated by the light as indicated by arrow 45 from a light emitting diode (LED) 50, creating an optical image 55 on the photoconductive support structure 25 via objective lens 57. The projected light as indicated by arrows 60 turns on the virtual electrodes creating non-uniform electric fields enabling particle manipulation via dielectriophoresis (DEP) forces.

Also known in the art are optical tweezers that rely entirely on optical forces to manipulate microscopic objects; they do not necessarily require dielectriophoresis (DEP) forces for the object manipulation. These devices have been extensively reviewed in the literature. For example, “Demonstration of trapping, motion control, sensing and fluorescence detection of polystyrene beads in a multi-fiber optical trap” by Cynthia Jensen-McMullin and Henry P. Lee, Optics Express, Vol. 13, No. 7, p. 2634 (4 Apr. 2005) describes an optical fiber-based embodiment of such an optical trapping system.

Lasers have been known to be attractive alternative light sources to lamps for illuminator systems. Laser illumination offers the potential for simple, low-cost efficient optical systems, providing improved efficiency and higher contrast. One disadvantage of lasers for illuminator systems use has been the lack of a cost-effective laser source with sufficient power at appropriate visible wavelengths.

Light valves that consist of a two-dimensional array of individually operable pixels arrayed in a rectangular geometry provide another component that enables pixilated laser illuminator systems. Examples of area light valves are reflective liquid crystal modulators such as the liquid-crystal-on-silicon (LCOS) modulators available from JVC, Three-Five, Aurora, and Philips, and micro-mirror arrays such as the Digital Light Processing (DLP) chips available from Texas Instruments. Advantages of two-dimensional modulators over one-dimensional array modulators and raster-scanned systems are the absence of scanning required, absence of streak artifacts due to nonuniformities in the modulator array, and immunity to laser noise at frequencies much greater than the frame refresh rate (≧120 Hz) in display systems. A further advantage of two-dimensional spatial light modulators is the tolerance for low spatial coherence of the illuminating beam. One-dimensional or linear light valves such as the Grating Light Valve (GLV) produced by Silicon Light Machines and conformal grating modulators require a spatially coherent illumination in the short dimension of the light valve.

When using an area light valve in an illuminator system requiring the use of RGB laser arrays, though, it would be desired to use fully integrated two-dimensional laser arrays. One of the few laser technologies that are easily integrable in two dimensions is the vertical-cavity surface-emitting laser (VCSEL).

VCSELs based on inorganic semiconductors (e.g. AlGaAs) have been developed since the mid-80's (S. Kinoshita et al., IEEE Journal of Quantum Electronics, Vol. QE-23, Number 6, [1987]). They have reached the point where AlGaAs-based VCSELs emitting at 850 nm are manufactured by a number of companies and have lifetimes beyond 100 years (K. D. Choquette et al., Proc. IEEE Vol. 85, No. 11, [1997]). With the success of these near-infrared lasers, attention in recent years has turned to other inorganic material systems to produce VCSELs emitting in the visible wavelength range (C. Wilmsen et al., Vertical-Cavity Surface-Emitting Lasers, Cambridge University Press, Cambridge, 2001). There are many potential applications for visible lasers, such as, display, optical storage reading/writing, laser printing, and short-haul telecommunications employing plastic optical fibers (T. Ishigure et al., Electronics Letters Vol. 31, No. 6 [1995]). In spite of the worldwide efforts of many industrial and academic laboratories, much work remains to be done to create viable laser diodes (either edge emitters or VCSELs) that produce light output that spans the visible spectrum.

In an effort to produce visible wavelength VCSELs it would be advantageous to abandon inorganic-based systems and focus on organic-based laser systems, since organic-based gain materials can enjoy a number of advantages over inorganic-based gain materials in the visible spectrum. For example, typical organic-based gain materials have the properties of low unpumped scattering/absorption losses and high quantum efficiencies. In comparison to inorganic laser systems, organic lasers are relatively inexpensive to manufacture, can be made to emit over the entire visible range, can be scaled to arbitrary size and, most importantly, are able to emit multiple wavelengths (such as red, green, and blue) from a single chip. Over the past number of years, there has been increasing interest in making organic-based solid-state lasers. The laser gain material has been either polymeric or small molecule and a number of different resonant cavity structures were employed, such as VCSEL (Kozlov et al., U.S. Pat. No. 6,160,828), waveguide, ring micro lasers, and distributed feedback (see also, for instance, G. Kranzelbinder et al., Rep. Prog. Phys. 63, pages 729-762 (2000) and M. Diaz-Garcia et al., U.S. Pat. No. 5,881,083). A problem with all of these structures is that in order to achieve lasing it was necessary to excite the cavities by optical pumping using another laser source. It is much preferred to electrically pump the laser cavities since this generally results in more compact and easier to modulate structures.

A main barrier to achieving electrically pumped organic lasers is the small carrier mobility of organic material, which is typically on the order of 10⁻⁵ cm²/(V-s). This low carrier mobility results in a number of problems. Devices with low carrier mobilities are typically restricted to using thin layers in order to avoid large voltage drops and ohmic heating. These thin layers result in the lasing mode penetrating into the lossy cathode and anode, which causes a large increase in the lasing threshold (V. G. Kozlov et al., J. Appl. Phys. Vol. 84, Number 8, pages 4096-4108 (1998)). Since electron-hole recombination in organic materials is governed by Langevin recombination (whose rate scales as the carrier mobility), low carrier mobilities result in orders of magnitude more charge carriers than singlet excitons; one of the consequences of this is that charge-induced (polaron) absorption can become a significant loss mechanism (N. Tessler et al., Appl. Phys. Lett. Vol. 74, Number 19, pages 2764-2766 (1999)). Assuming laser devices have a 5% internal quantum efficiency, using the lowest reported lasing threshold to date of ˜100 W/cm² (M. Berggren et al., Letters to Nature Vol. 389, page 466-469 (1997)), and ignoring the above mentioned loss mechanisms, would put a lower limit on the electrically-pumped lasing threshold of 1000 A/cm². Including these loss mechanisms would place the lasing threshold well above 1000 A/cm², which to date is the highest reported current density, which can be supported by organic devices (N. Tessler, et al., Advanced Materials (1998)), 10, No. 1, pages 64-68.

One way to avoid these difficulties is to use crystalline organic material instead of amorphous organic material as the lasing media. This approach was recently taken (J. H. Schon, Science 289, 599 (2000)) where a Fabry-Perot resonator was constructed using single crystal tetracene as the gain material. By using crystalline tetracene larger current densities can be obtained, thicker layers can be employed (since the carrier mobilities are on the order of 2 cm²/(V-s)), and polaron absorption is much lower. This resulted in room temperature laser threshold current densities of approximately 1500 A/cm².

One of the advantages of organic-based lasers is that since the gain material is typically amorphous, devices can be formed inexpensively when compared to lasers with gain materials that require a high degree of crystallinity (either inorganic or organic materials). Additionally, lasers based upon organic amorphous gain materials can be fabricated over large areas without regard to producing large regions of single crystalline material. As a result they can be scaled to arbitrary size resulting in greater output powers. Because of their amorphous nature, organic-based lasers can be grown on a wide variety of substrates; thus, materials such as glass, flexible plastics, and Si are possible supports for these devices. Thus there can be significant cost advantages as well as a greater choice in usable support materials for amorphous organic-based lasers; the usage of single crystal organic lasers would obviate all of these advantages.

An alternative to electrical pumping for organic lasers is optical pumping by incoherent light sources, such as, light emitting diodes (LEDs), either inorganic (M. D. McGehee et al. Appl. Phys. Lett. Vol. 72, No. 13, pages 1536-1538 [1998]) or organic (Berggren et al., U.S. Pat. No. 5,881,089). This possibility is the result of unpumped organic laser systems having greatly reduced combined scattering and absorption losses (˜0.5 cm⁻¹) at the lasing wavelength, especially when one employs a host-dopant combination as the active media. Even taking advantage of these small losses, the smallest reported optically pumped threshold for organic lasers to date is 100 W/cm² based on a waveguide laser design (M. Berggren et al., Nature 389, 466 (1997)). Since off-the-shelf inorganic LEDs can only provide up to ˜20 W/cm² of power density, it is necessary to take a different route to make avail of optically pumping by incoherent sources. In order to lower the lasing threshold additionally, it is necessary to choose a laser structure which minimizes the gain volume; a VCSEL-based microcavity laser satisfies this criterion. Using VCSEL-based organic laser cavities should enable optically pumped power density thresholds below 5 W/cm². As a result, practical organic laser devices can be driven by optically pumping them with a variety of readily available, incoherent light sources, such as LEDs. Furthermore, because the pump LEDs can be arrayed over an area, the organic laser can be built into two-dimensional arrays.

### SUMMARY OF THE INVENTION

In general terms, the present invention is an array of organic vertical cavity laser device for manipulating microscopic objects.

One aspect of the present invention is a method of manipulating objects. The method includes providing a support for locating objects, providing a laser array assembly having a plurality of organic vertical cavity laser devices, imaging the plurality of organic laser devices onto the support, and manipulating the objects disposed on the support by controlling the plurality of the organic vertical cavity laser devices to vary an optical image on the support.

Another aspect of the present invention is directed to a system for manipulating objects. The system includes a support to locate objects, a laser array assembly having a plurality of organic vertical cavity laser devices, an objective lens to project an image generated by the plurality of the organic vertical cavity laser devices onto the support, and a control device to control the plurality of the organic vertical cavity laser devices to vary the image on the support and manipulate the objects disposed on the support.

Another aspect of the present invention is a method of manipulating objects. The method includes providing a support for locating objects, providing a combination illuminator having a plurality of illuminating components, and manipulating the objects disposed on the support by controlling the plurality of the organic vertical cavity laser devices to vary an optical image on the support.

Yet another aspect of the present invention is a system of manipulating objects. The system includes a support to locate objects, a combination illuminator having a plurality of illuminating components, and an objective lens to project an image generated by the plurality of the organic vertical cavity laser devices onto the support, and a control device to control the plurality of the organic vertical cavity laser devices to vary the image on the support and manipulate the objects disposed on the support.

### BRIEF DESCRIPTION OF THE DRAWINGS

FIG. 1 is a schematic illustrating an optoelectronic tweezers (OET) device used to manipulate biological cells and micrometer-scale particles as disclosed in the prior art;

FIG. 2A is a schematic illustrating an optoelectronic tweezers (OET) device made in accordance with the present invention;

FIG. 2B is a schematic illustrating another embodiment of the optoelectronic tweezers (OET) device made in accordance with the present invention;

FIG. 3 is a cross-section side view schematic of an optically pumped organic vertical cavity laser device;

FIG. 4 is a cross-section side view schematic of an optically pumped organic vertical cavity laser with a periodically structured organic gain region;

FIG. 5 shows an organic vertical cavity laser structure made in accordance with the present invention in which a two-dimensional arrangement of organic vertical cavity laser devices is depicted;

FIG. 6A depicts an organic vertical cavity laser structure in which sub-arrays of different wavelength organic vertical cavity laser devices are fabricated;

FIG. 6B depicts an organic vertical cavity laser structure in which sub-arrays may be dynamically tuned to different wavelengths;

FIG. 6C is a cross-section side view of an optically pumped tunable organic vertical cavity laser;

FIG. 7 illustrates a view of the organic vertical cavity laser assembly comprising the organic vertical cavity laser array and a pump beam light source made in accordance with the present invention;

FIG. 8 illustrates an optical intensity or illumination pattern created by the organic vertical cavity laser array of FIGS. 6A and 6B made in accordance with the present invention;

FIG. 9A illustrates another embodiment of the present invention where the optical illumination patterns from the digital micro mirror display and organic vertical cavity laser array assembly are combined to create a composite image in accordance with the present invention; and

FIG. 9B illustrates yet another embodiment of the present invention where the output from an inorganic vertical cavity laser and organic vertical cavity laser array assembly are combined to create a composite image in accordance with the present invention.

### DETAILED DESCRIPTION OF THE INVENTION

Various embodiments of the present invention will be described in detail with reference to the drawings, wherein like reference numerals represent like parts and assemblies throughout the several views. Reference to various embodiments does not limit the scope of the invention, which is limited only by the scope of the claims attached hereto. Additionally, any examples set forth in this specification are not intended to be limiting and merely set forth some of the many possible embodiments for the claimed invention.

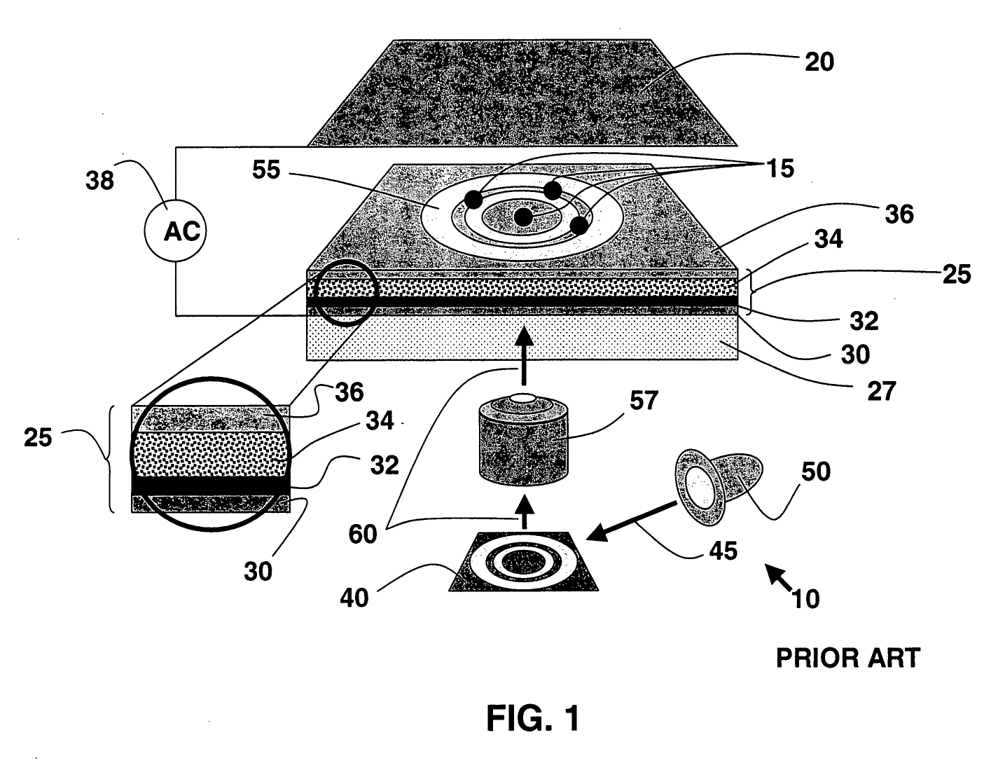

Instead of using the digital micro mirror display (DMD) 40 and the light emitting diode (LED) 50 in FIG. 1 and it's complicated assembly, it is advantageous to replace these two components with an array of organic lasers. Organic materials-based lasers can be fabricated over large areas and grown on a variety of substrates such as glass, silica and most importantly flexible plastics. Organic lasers are available in abroad range of output wavelengths allowing optimization with specific photoconductive material. In the present invention, the terminology describing organic vertical cavity laser devices (VCSELs) may be used interchangeably in a short hand fashion as “organic laser cavity devices.” Organic laser cavity structures are fabricated as large area structures and optically pumped with light emitting diodes (LEDs).

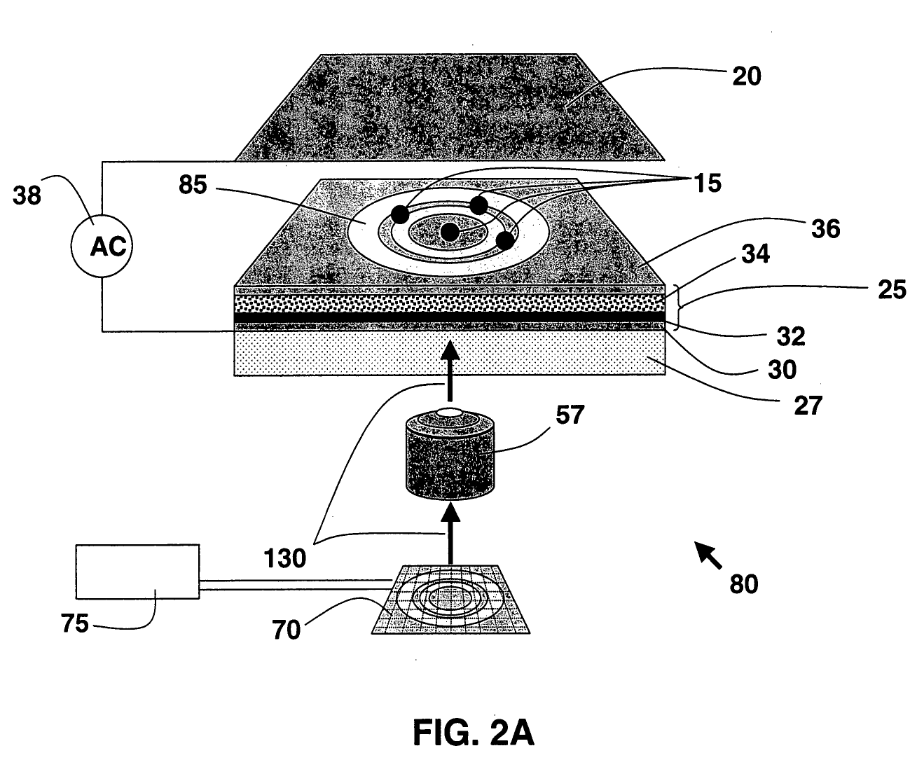

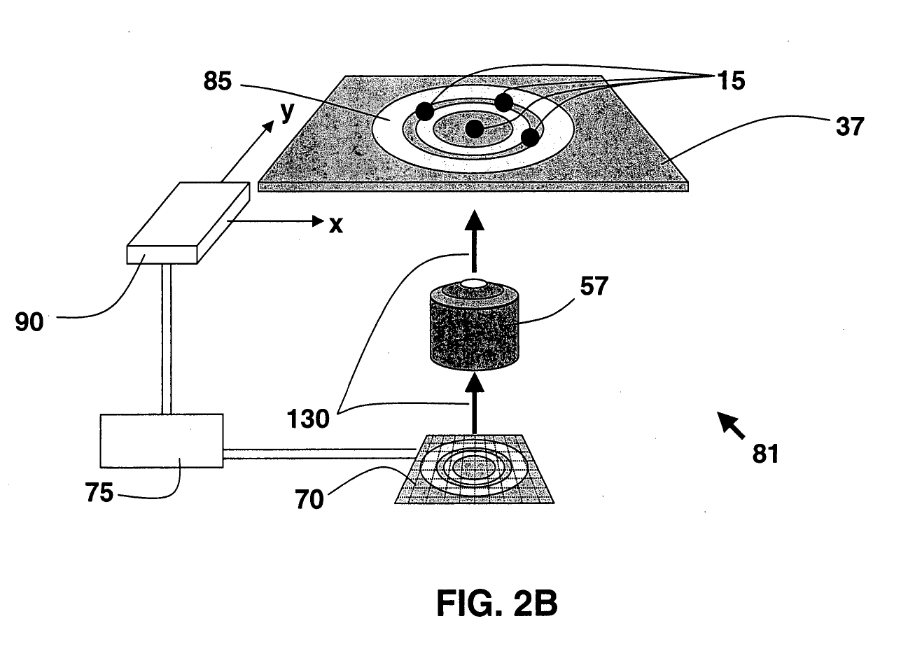

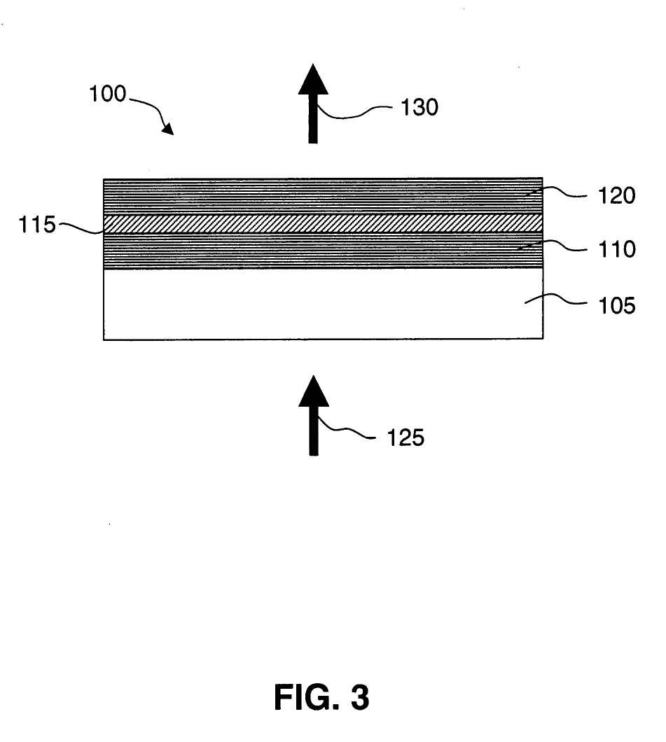

In the embodiment shown in FIG. 2A the LED and micro mirror illumination source of the optoelectronic tweezers described in FIG. 1 are replaced with an organic vertical cavity laser array assembly 70 which includes a pump light source as described in FIGS. 3, 4, 5 and 7 and in U.S. Pat. No. 6,853,660, Spoonhower et al., incorporated herein by reference. The result is an inexpensive, high brightness, compact, and versatile illumination source whose light output can be tuned over a large wavelength range. The organic vertical cavity laser array assembly 70 consists of a plurality of organic vertical cavity lasers and is capable of easily producing any type of illumination pattern because of the individual addressability of and control of each laser in the array. Referring to FIG. 2A, a schematic of an optoelectronic tweezers (OET) device 80 made in accordance with the present invention is illustrated. The LED 50 and micro mirror 40 illumination source described in FIG. 1 are replaced with the organic laser array assembly 70, which emits a laser beam 130 to form the optical image 85. The image 85 may vary in time. For example, a time-varying projection of a series of concentric circles as shown in FIG. 2A where the radius of each concentric circles is reduced would cause the micrometer-scale particles 15 to move to the center of the circular pattern and become more concentrated in that spatial region. The organic laser array assembly 70 may be programmed to create a varying pattern of illumination suitable for this use. A computer controller 75 is used to establish the pattern of illuminated pixels in the organic laser array assembly 70.

The optical transmission of photoconductive support structure 25 varies with the optical wavelength. This so-called optical transmission spectrum can be quite complex, with several wavelengths where maximum transmission occurs. Referring to FIG. 1, the photoconductive support structure 25 consists of several featureless layers of ITO-coated glass 30, an n⁺ hydrogenated amorphous silicon (a-Si:H) layer 32, an undoped a-Si:H layer 34, and a silver nitride layer 36. The optical transmission of the photoconductive support structure 25 is determined by the optical transmission spectrum of each of the individual layers making up the photoconductive support structure 25. One can optimize the performance of the optoelectronic (OET) tweezers device by selecting output wavelengths of the organic laser array assembly with pumped beam light source 70 corresponding to the maxima in the optical transmission spectrum of the photoconductive support structure 25. Methods of selecting the output wavelength are disclosed in greater detail below.

In another embodiment as shown in FIG. 2B, the photoconductive support structure 25 is replaced by a support 37 that is movable in at least the x and y direction by a translator 90, as shown by the optoelectronic tweezers (OET) device 81. However, the embodiment is not limited to the x and y directions, and the support structure 25 can be moved in any suitable direction. This enables a larger control range for the position of the micrometer-scale particles 15. Through the use of the translator 90 spatial regions of an extended support 37 are selected and the particles within that region are manipulated by varying the optical image 85 on the support 37. The use of such a translator 90 to extend the range of light-based control is obvious to those skilled in the art. The embodiment shown in FIG. 2B also differs from the embodiment shown in FIG. 2A by the lack of elements necessary to establish an electric field and manipulate the micrometer-scale particles 15 by dielectriophoresis (DEP) forces. These elements include the photoconductive support structure 25, the conductive ITO-coated glass 20, and the AC signal generator 38. In this embodiment, the forces used to manipulate and control the position of the micrometer-scale particles 15 arise from the intensity distribution of the optical image 85 itself. For example, a suitably bright spot with a Gaussian intensity profile will trap a particle 15; subsequent movement of the spot will control the position of the particle. In this case, the optimum wavelength is affected by the optical properties of the particles themselves. Particles with differing optical properties will experience differences in the manipulating forces with different light wavelengths. This physical phenomenon offers a mechanism for enhanced capability in the control of the particles position.

A schematic of an organic vertical cavity laser device 100 is shown in FIG. 3. The substrate 105 can either be light transmissive or opaque, depending on the intended direction of optical pumping or laser emission. Light transmissive substrates 105 may be transparent glass, sapphire, or other transparent flexible materials such as plastic. Alternatively, opaque substrates including, but not limited to, semiconductor material (e.g. silicon) or ceramic material may be used in the case where both optical pumping and emission occur through the same surface. On the substrate is deposited a bottom dielectric stack 110 followed by an organic active region 115. A top dielectric stack 120 is then deposited on the organic active region 115. A pump beam 125 optically pumps the organic vertical cavity laser device 100. The source of the pump beam 125 may be incoherent, such as emission from a light-emitting diode (LED).

The preferred material for the organic active region 115 is a small-molecular weight organic host-dopant combination typically deposited by high-vacuum thermal evaporation. These host-dopant combinations are advantageous since they result in very small unpumped scattering/absorption losses for the gain media. It is preferred that the organic molecules be of small molecular weight since vacuum deposited materials can be deposited more uniformly than spin-coated polymeric materials. Host materials used in the present embodiment are selected such that they have sufficient absorption of the pump beam 125 and are able to transfer a large percentage of their excitation energy to a dopant material via Förster energy transfer. Those skilled in the art are familiar with the concept of Förster energy transfer, which involves a radiationless transfer of energy between the host and dopant molecules. An example of a useful host-dopant combination for red-emitting lasers is aluminum tris(8-hydroxyquinoline) (Alq) as the host and [4-(dicyanomethylene)-2-t-butyl-6-(1,1,7,7-tetramethyljulolidyl-9-enyl)-4H-pyran] (DCJTB) as the dopant (at a volume fraction of 1%). Other host-dopant combinations can be used for other wavelength emissions. For example, in the green a useful combination is Alq as the host and [10-(2-benzothiazolyl)-2,3,6,7-tetrahydro-1,1,7,7-tetramethyl-1H,5H,11H-[1]Benzopyrano[6,7,8-ij]quinolizin-11-one] (C545T) as the dopant (at a volume fraction of 0.5%). Other organic gain region materials can be polymeric substances, e.g., polyphenylenevinylene derivatives, dialkoxy-polyphenylenevinylenes, poly-para-phenylene derivatives, and polyfluorene derivatives, as taught by Wolk et al. in commonly assigned U.S. Pat. No. 6,194,119 B1, issued Feb. 27, 2001, and referenced herein. It is the purpose of the organic active region 115 to receive transmitted pump beam light 125 and emit laser light.

The bottom and top dielectric stacks 110 and 120, respectively, are preferably deposited by conventional electron-beam deposition and can comprise alternating high index and low index dielectric materials, such as, TiO₂ and SiO₂, respectively. Other materials, such as Ta₂O₅ for the high index layers, could be used. The bottom dielectric stack 110 is deposited at a temperature of approximately 240° C. During the top dielectric stack 120 deposition process, the temperature is maintained at around 70° C. to avoid melting the organic active materials. In an alternative embodiment, the top dielectric stack is replaced by the deposition of a reflective metal mirror layer. Typical metals used in the mirror layer are silver or aluminum, which have reflectivities in excess of 90%. In this alternative embodiment, both the pump beam 125 and the laser emission 130 would proceed through the substrate 105. Both the bottom dielectric stack 110 and the top dielectric stack 120 are reflective to laser light over a predetermined range of wavelengths, in accordance with the desired emission wavelength of the laser cavity 100.

The use of a vertical microcavity laser with very high finesse allows a lasing transition at a very low threshold (below 0.1 W/cm² power density). This low threshold enables incoherent optical sources to be used for the pumping instead of the focused output of laser diodes, which is conventionally used in other laser systems. An example of a pump source is a UV LED, or an array of UV LEDs, e.g. from Cree (specifically, the XBRIGHT® 900 UltraViolet Power Chip® LEDs). These sources emit light centered near 405 nm wavelength and are known to produce power densities on the order of 20 W/cm² in chip form. Thus, even taking into account limitations in utilization efficiency due to device packaging and the extended angular emission profile of the LEDs, the LED brightness is sufficient to pump the laser cavity at a level many times above the lasing threshold.

Organic lasers open up a more viable route to output that spans the visible spectrum. Organic based gain materials have the properties of low un-pumped scattering/absorption losses and high quantum efficiencies. VCSEL based organic laser cavities can be optically pumped using an incoherent light source such as light emitting diodes (LED) with lasing power thresholds below 5 W/cm².

One advantage of organic-based lasers is that since the gain material is typically amorphous, devices can be formed inexpensively when compared to lasers with gain materials that require a high degree of crystallinity. Lasers based on amorphous gain materials can be fabricated over large areas without regard to producing large regions of a single crystalline material and can be scaled to arbitrary size resulting in greater power output. Because of the amorphous nature, organic based lasers can be grown on a variety of substrates, thus, materials such as glass, flexible plastics and Si are possible supports for these devices.

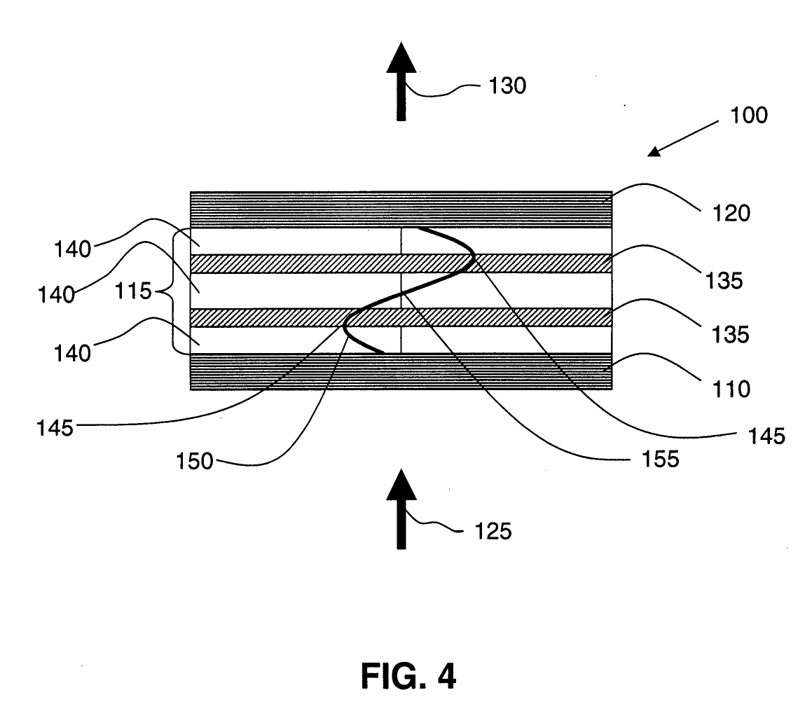

FIG. 4 is a cross-section side view schematic of an optically pumped organic vertical cavity laser with a periodically structured organic gain region. The efficiency of the laser is improved further using an active region design as depicted in FIG. 4 for the organic vertical cavity laser device 100. The organic active region 115 includes one or more periodic gain regions 135 and organic spacer layers 140 disposed on either side of the periodic gain regions 135. The spacer layers 140 are arranged so that the periodic gain regions 135 are aligned with antinodes 145 of the device's standing wave electromagnetic field. This is illustrated in FIG. 4 where the laser's standing electromagnetic field pattern 150 in the organic active region 115 is schematically drawn. Since stimulated emission is highest at the antinodes 145 and negligible at nodes 155 of the electromagnetic field, it is inherently advantageous to form the active region 115. The organic spacer layers 140 do not undergo stimulated or spontaneous emission and largely do not absorb either the laser emission 130 or the pump beam 125 wavelengths. An example of a spacer layer 140 is the organic material 1,1-Bis-(4-bis(4-methyl-phenyl)-amino-phenyl)-cyclohexane (TAPC). TAPC works well as the spacer layer material since it largely does not absorb either the laser emission 130 or the pump beam 125 energy and, in addition, its refractive index is slightly lower than that of most organic host materials. This refractive index difference is useful since it helps in maximizing the overlap between the electromagnetic field antinodes and the periodic gain region(s) 135. As will be discussed below, employing periodic gain region(s) 135 instead of a bulk gain region results in higher power conversion efficiencies and a significant reduction of the unwanted spontaneous emission.

The placement of the periodic gain region(s) 135 is determined by using the standard matrix method of optics (Corzine et al. IEEE Journal of Quantum Electronics, Volume 25, No. 6, June 1989). To get good results, the thicknesses of the periodic gain region(s) 135 need to be at or below 50 nm in order to avoid unwanted spontaneous emission.

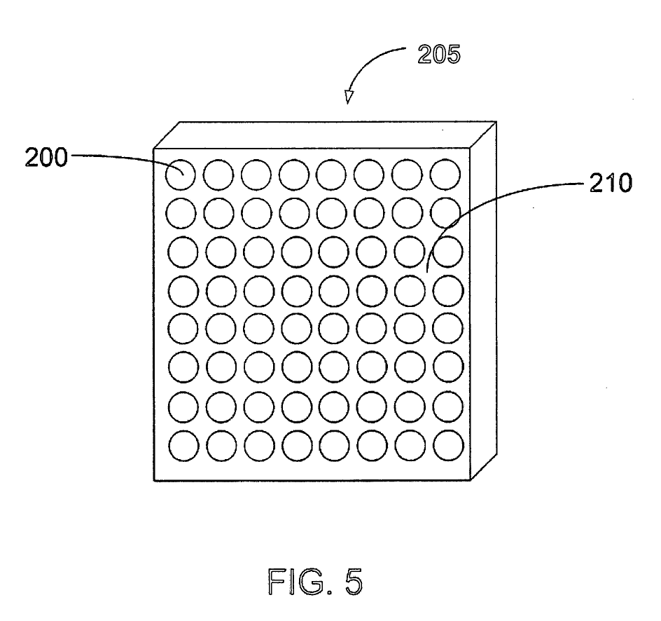

FIG. 5 illustrates one embodiment of an organic laser cavity structure in which a two-dimensional arrangement of a plurality of organic vertical cavity laser devices is depicted. Fabricating organic laser cavity devices 200 in a regular pattern that extends in 2 dimensions forms such a two-dimensional organic laser cavity structure 205. The inter-pixel regions 210 generally consist of non-lasing portions of the structure that separate the organic laser cavity devices 200.

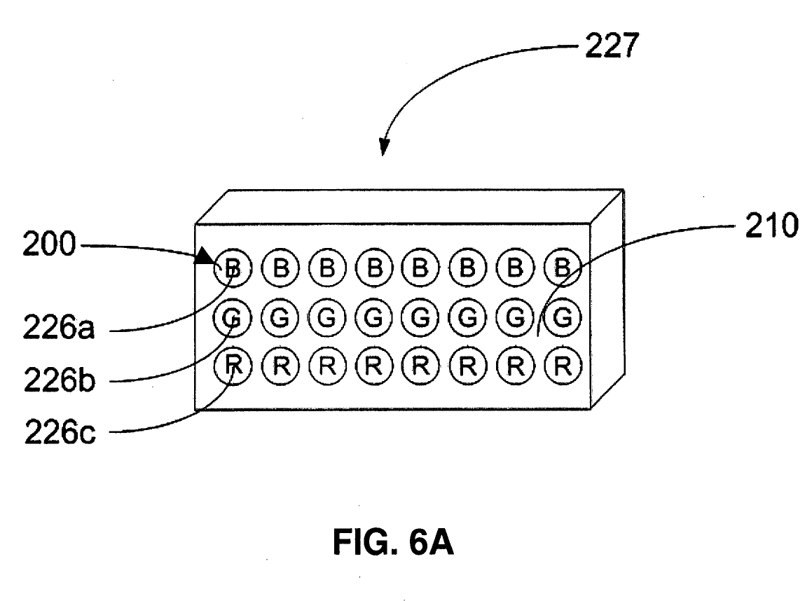

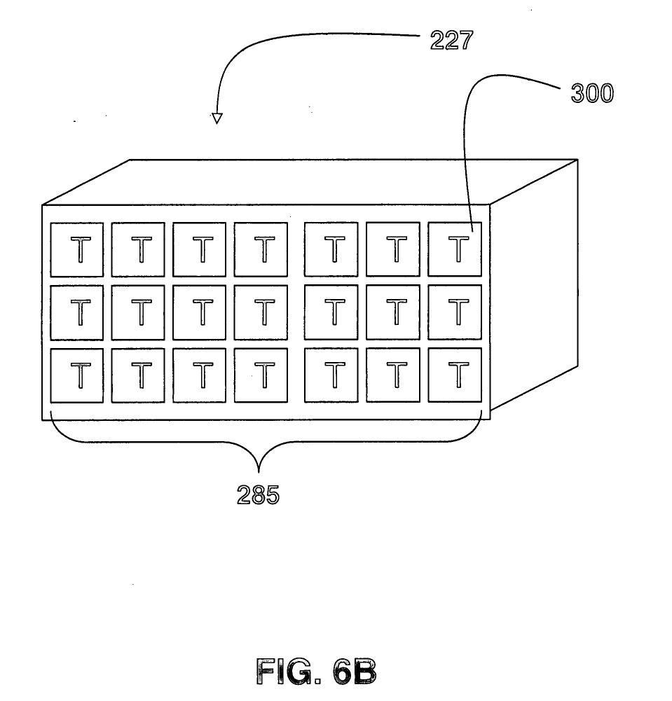

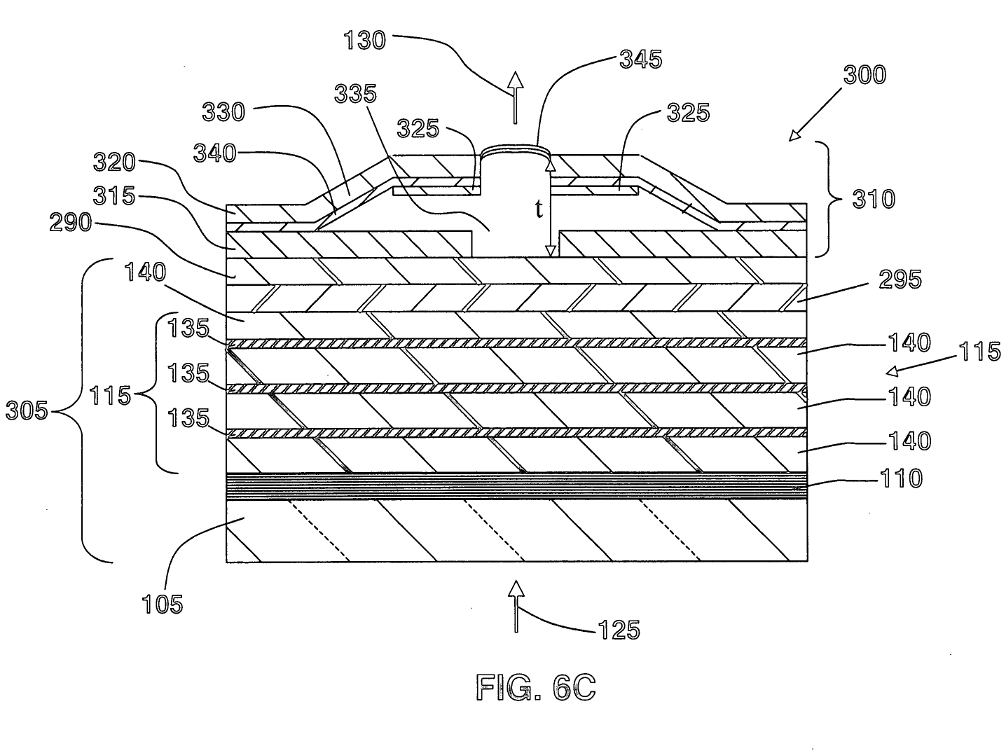

FIG. 6A depicts an embodiment of an organic laser cavity structure 227 in which sub-structures of different wavelength organic laser cavity devices 200 are fabricated. A multiwavelength organic laser cavity structure 227 has sub-structures of red (r) 226a, green (g) 226b, and blue (b) 226c regions, separated by interpixel regions 210. The two-dimensional organic laser cavity structure 227 produces a multiwavelength light output, where the laser light emission is designed to occur at discrete wavelengths in the red (R), green (G), and blue (B) regions of the optical spectrum. The red region of the optical spectrum approximately corresponds to the wavelength range of 600-650 nm. The green region of the optical spectrum approximately corresponds to the wavelength range of 500-550 nm, and the blue region of the optical spectrum approximately corresponds to the wavelength range of 450-500 nm. With the proper design of the organic laser cavity device 200, the light output wavelength can be specified throughout the visible optical spectrum (approximately 450-700 nm). It is to be understood that different wavelength pump-beam light can be used to produce a substantially single wavelength output. This can be accomplished through the proper design of the dielectric stack materials and thicknesses, the choice of the organic active region 115 materials (FIG. 4), and the cavity dimensions. Alternatively, single wavelength pump-beam light can produce multiple substantially different wavelength outputs. Again this is accomplished by design of the various organic laser cavity devices 200 in the structure. It is also to be understood that any of the organic laser cavity structures can be designed and fabricated so as to produce a multiwavelength light output suitable for the application at hand. In addition the degree of coherence of the various organic laser cavity devices 200 may be controlled via a number of mechanisms. One such mechanism involves lowering the microcavity finesse to reduce the laser coherence.

Changes in both the bottom dielectric stack 110 and the top dielectric stack 120 (FIG. 4) can reduce the reflectivity at the lasing wavelength and would affect the laser coherence. Alternatively, individual organic laser cavity devices 200 may have their light output combined optically with reduced coherence if the distance in the array 70 (FIG. 2A) is large enough to preclude coupling of the individual organic laser cavity devices 200. Separation distances larger that approximately 20 micron would decouple the individual organic laser cavity devices 200.

FIG. 6B depicts an organic laser cavity structure 227 in which sub-arrays 285 comprised of optically pumped organic vertical cavity laser systems 300 may be dynamically tuned to different wavelengths.

FIG. 6C is a cross-section side view of an optically pumped organic vertical cavity laser system 300. The system 300 employs a multi-layered film structure 305 with a periodically structured organic gain region and with MEMs (micro-electromechanical system) device for changing the optical path length of the laser cavity. The vertical cavity laser system 300 is best described by considering two separate subsystems: the multi-layered film structure 305 and the micro-electromechanical mirror assembly 310. The multi-layered film structure 305 consists of the substrate 105, the bottom dielectric stack 110, the organic active region 115, and one or more index matching layers 290 and 295. In this case, the substrate 105 is transmissive for light of the pump beam 125. Pump beam 125 light is received by the multi-layered film structure 305 and produces spontaneous emission. The top dielectric stack 345 and the bottom dielectric stack 110 constitute the end mirrors of the organic laser cavity. The micro-electromechanical mirror assembly 310 consists of a bottom electrode 315, a support structure 320, a top electrode 325, support arms 330, an air gap 335, a mirror tether 340, and the top dielectric stack 345. Laser emission 130 occurs from the top dielectric stack 345. A voltage source (not shown) applied between the bottom electrode 315 and the top electrode 325 changes the thickness t, of the air gap 335 via electrostatic interaction and thereby varies the cavity length of the organic laser cavity device. This variation of the organic laser cavity length causes a wavelength variation of the optically pumped tunable vertical cavity organic laser system 300. A tunable organic vertical cavity laser system is described in U.S. Pat. No. 6,970,488 by J. P. Spoonhower et. al. and is hereby incorporated by reference.

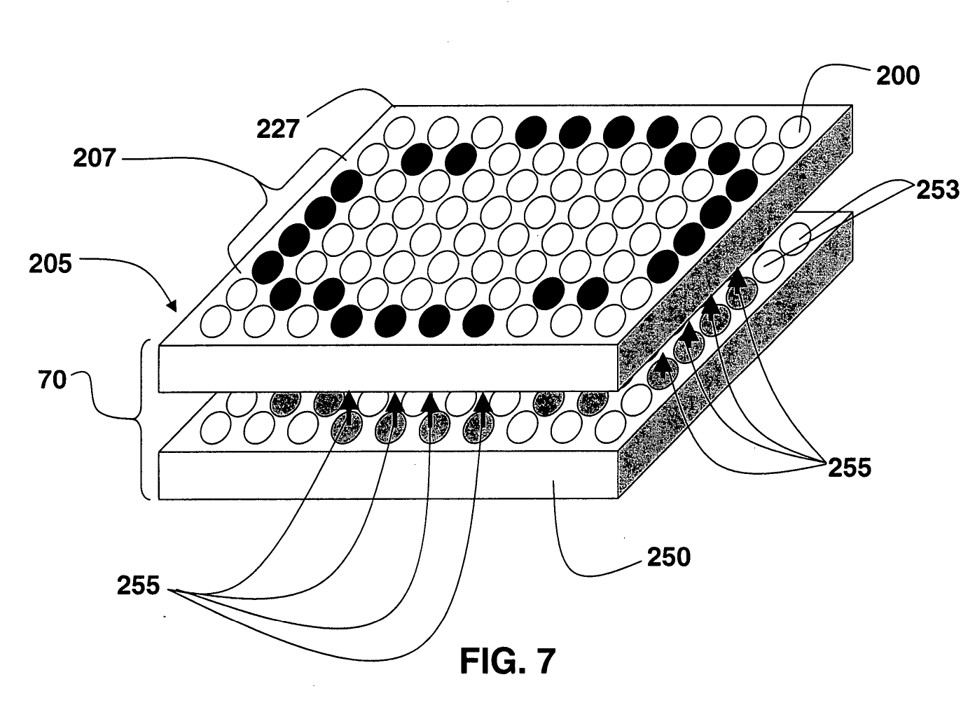

FIG. 7 illustrates a view of the organic vertical cavity laser assembly 70 comprising the vertical cavity organic laser array 227 and a pump beam light source 250 for optically pumping light 255 to the organic laser array 227. In the embodiment shown the pump beam light source 250 is an array formed by individual light sources 253 whose pattern matches the pattern of the vertical cavity organic laser array 227. Individual light emitting diodes (LEDs) are examples of the individual light sources 253. The illuminating pattern 207 once imaged is used to manipulate the particles 15 (FIG. 1) position.

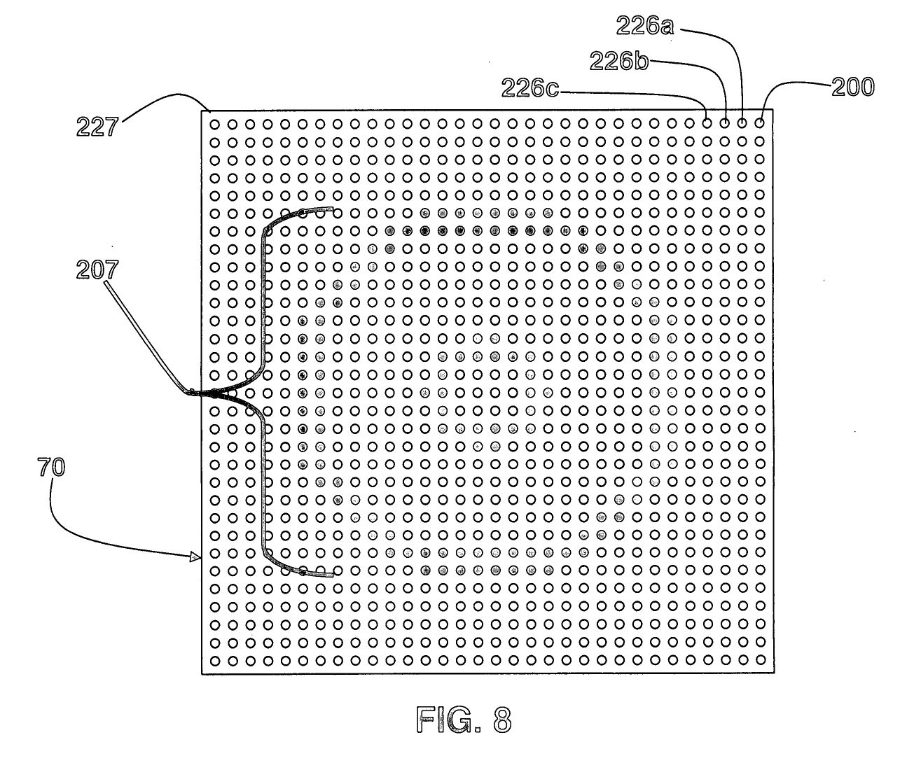

FIG. 8 illustrates one embodiment of a multiwavelength organic laser cavity array 227. The array 227 uses sub-structures of red (r) 226a, green (g) 226b, and blue (b) 226c to create an illuminated pattern 207 that is focused onto the photoconductive support structure 25 via lens 57 as shown in FIG. 2A or on a support 37 as shown in FIG. 2B. The projected optical image 85 (FIG. 2A) is used to manipulate the particles on the support 25, for example, via either dielectriophoresis or photon forces as previously discussed. It has been found the different particles react differently to particular wavelengths the multiwavelength organic laser cavity array 227 can be wavelength tuned to produce the image 85 with the optimum response to manipulate a particular particle 15, for example, within a mixture of particles.

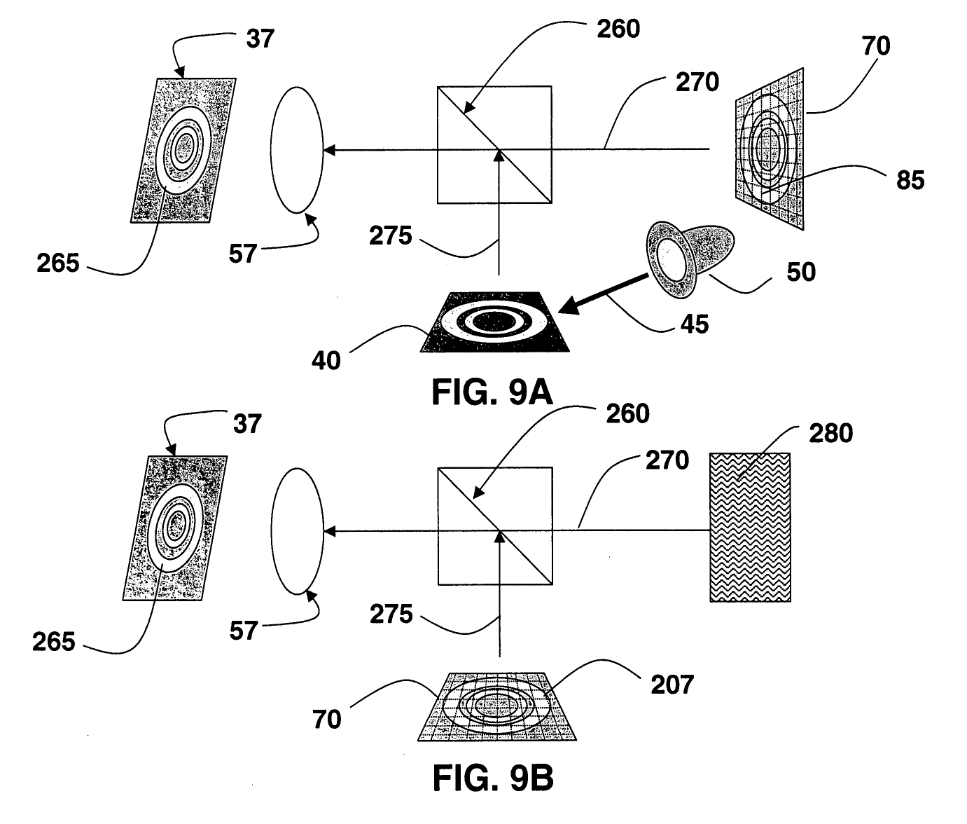

FIG. 9A is another embodiment illustrating an optical manipulator illuminated by patterned organic microcavity lasers. Light from the digital micro mirror display (DMD) 40 illuminated by the light emitting diode (LED) 50 is combined with the optical illuminant 207 from organic vertical cavity laser array assembly 70 by a beam splitter 260 as indicated by arrows 270 and 275 creating a composite optical image 265 which is focused onto the support 37 via objective lens 57.

FIG. 9B is yet another embodiment illustrating an optical manipulator illuminated by patterned organic microcavity lasers. In FIG. 9B, the light output from an inorganic laser 280 providing a spatially uniform illuminant is combined with the optical illuminant 207 from organic vertical cavity laser array assembly 70 by a beam splitter 260 as indicated by arrows 270 and 275 creating a composite optical image 265 which is focused onto the support 37 via objective lens 57. In both FIGS. 9A and 9B the use of the additional illuminating light from the inorganic laser 280, or the light from the LED 50 modified by the digital micro mirror display (DMD) 40 to create an illuminating pattern offsets the available form the organic vertical cavity laser array assembly 70 when used alone. This combination of illuminants can provide greater flexibility in manipulating the positions of particles 15.

The various embodiments described above are provided by way of illustration only and should not be construed to limit the invention. Those skilled in the art will readily recognize various modifications and changes that may be made to the present invention without following the example embodiments and applications illustrated and described herein, and without departing from the true spirit and scope of the present invention, which is set forth in the following claims.

### PARTS LIST

10 optoelectronic (OET) tweezers device
15 micrometer-scale particles
20 conductive ITO-coated glass
25 photoconductive support structure
27 glass substrate
30 ITO-coated glass
32 n⁺ hydrogenated amorphous silicon (a-Si:H) layer
34 undoped a-Si:H layer
36 silver nitride layer
37 support
38 AC signal generator
40 digital micro mirror display (DMD)
45 arrow
50 light emitting diode (LED)
55 image
57 objective lens
60 arrow
70 organic vertical cavity laser array assembly with pumped beam light source
75 computer controller
80 optoelectronic (OET) tweezers device
85 image
90 translator
100 organic vertical cavity laser device
105 substrate
110 bottom dielectric stack
115 organic active region
120 top dielectric stack
125 pump beam
130 laser beam/emission
135 periodic gain regions
140 organic spacer layers
145 antinodes
150 electromagnetic field pattern
155 nodes
200 organic laser cavity device
205 two-dimensional organic laser cavity structure
207 pattern
210 inter-pixel regions
226a, b, c, red, green, blue
227 multiwavelength organic laser cavity structure
230 illuminated pattern
250 pumped beam light source
253 light sources
255 pumped light
260 beam splitter
265 composite image
270 arrow
275 arrow
280 inorganic laser.
285 sub-arrays
290 index matching layers
295 index matching layers
300 optically pumped organic vertical cavity laser system
305 multi-layered film structure
310 micro-electromechanical mirror assembly
315 bottom electrode
320 support structure
325 top electrode
330 support arms
335 air gap
340 mirror tether
345 top dielectric stack

What is claimed is:

1. A method of manipulating objects, comprising:
providing a support for locating objects;
providing a laser array assembly having a plurality of organic vertical cavity laser devices;
imaging the plurality of organic laser devices onto the support; and
manipulating the objects disposed on the support by controlling the plurality of the organic vertical cavity laser devices to vary an optical image on the support.

2. The method of claim 1, wherein providing the support further comprises providing a support containing a photoconductive structure.

3. The method of claim 1, wherein providing the support further comprises providing a movable stage.

4. The method of claim 1, wherein providing the plurality of organic laser devices further comprises providing a plurality of organic vertical cavity laser devices each having multiple optical wavelength outputs.

5. The method of claim 4, wherein providing a plurality of organic vertical cavity laser devices further comprises providing one or more laser devices having a fixed wavelength.

6. The method of claim 4, wherein providing the plurality of organic vertical cavity laser devices further comprises providing tunable organic vertical cavity laser devices.

7. The method of claim 4, wherein providing the plurality of organic vertical cavity laser devices further comprises providing a first laser device having an output wavelength different from the wavelength of a second laser device.

8. The method of claim 1, wherein providing the plurality of organic vertical cavity laser devices further comprises providing each laser device output arranged in a pattern.

9. The method of claim 1, wherein the laser array assembly further providing a pump light source.

10. A system for manipulating objects, comprising:
a support to locate objects;
a laser array assembly having a plurality of organic vertical cavity laser devices;
an objective lens to project an image generated by the plurality of the organic vertical cavity laser devices onto the support; and
a control device to control the plurality of the organic vertical cavity laser devices to vary the image on the support and manipulate the objects disposed on the support.

11. The system of claim 10, wherein each of the organic vertical cavity laser devices provides multiple optical wavelength outputs.

12. The system of claim 11, wherein one or more of the organic vertical cavity laser devices have an output fixed at a specific wavelength.

13. The system of claim 11, wherein a first organic vertical cavity laser device has an output wavelength different from a second organic vertical cavity laser device.

14. The system of claim 11, wherein an output of the organic laser vertical cavity devices is arranged in a desired pattern.

15. The system of claim 11, wherein the organic laser devices further comprises tunable organic vertical cavity laser devices.

16. The system of claim 10, wherein the laser array assembly further comprises a pump light source.

17. The system of claim 16, wherein the pump light source further comprises an incoherent optical source to provide laser transitions at a threshold less than 0.1 W/cm².

18. A method of manipulating objects, comprising:
providing a support for locating objects;
providing a combination illuminator having a plurality of illuminating components; and
manipulating the objects disposed on the support by controlling the plurality of the organic vertical cavity laser devices to vary an optical image on the support.

19. The method of claim 18, wherein the plurality of illuminating components further comprises providing a plurality of organic laser devices and an incoherent modulated light source.

20. The method of claim 18, wherein the plurality of illuminating components further comprises providing a plurality of organic laser devices and an inorganic laser light source.

21. A system of manipulating objects, comprising:
a support to locate objects;
a combination illuminator having a plurality of illuminating components; and
an objective lens to project an image generated by the plurality of the organic vertical cavity laser devices onto the support; and
a control device to control the plurality of the organic vertical cavity laser devices to vary the image on the support and manipulate the objects disposed on the support.

22. The system of claim 21, wherein the plurality of illuminating components further comprises a plurality of organic laser devices and an incoherent modulated light source.

23. The system of claim 21, wherein the plurality of illuminating components further comprises a plurality of organic laser devices and an inorganic laser light source.
